(19) United States
(12) Patent Application Publication
(10) Pub. No.: US 2005/0255661 A1
(43) Pub. Date: Nov. 17, 2005

(54) Semiconductor device and manufacturing method therefor

(76) Inventor: Ryota Katsumata, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/954,173

(22) Filed: Oct. 1, 2004

(30) Foreign Application Priority Data
May 13, 2004 (JP) 2004-143443

(51) Int. Cl. H01L 21/8238; H01L 21/8242; H01L 21/331; H01L 21/8222; H01L 29/76; H01L 29/94; H01L 31/062; H01L 31/113; H01L 31/119

(52) U.S. Cl. 438/314; 257/391

(57) ABSTRACT

A semiconductor memory device includes a semiconductor substrate having a first region and a second region, a first gate insulating film which is formed on the semiconductor substrate in the first region, a first electrode layer which is formed on the first gate insulating film, a first silicide layer which is formed on the first electrode layer, a first cap layer which is formed on the first silicide layer, a second gate insulating film which is formed on the semiconductor substrate in the second region, a second electrode layer which is formed on the second gate. insulating film, a second silicide layer which is formed on the second electrode layer, and a second cap layer which is formed on the second silicide layer and is thinner than the first cap layer.

### CROSS-REFERENCE TO RELATED APPLICATIONS

This application is based upon and claims the benefit of priority from prior Japanese Patent Application No. 2004-143443, filed May 13, 2004, the entire contents of which are incorporated herein by reference.

### BACKGROUND OF THE INVENTION

1. Field of the Invention

The present invention relates to a semiconductor device having gate stack structures with different heights, and a manufacturing method therefor.

2. Description of the Related Art

Recently, the demand for smaller peripheral circuits has increased as the DRAM (Dynamic Random Access Memory) chip size reduces. In the peripheral circuit region, a required circuit pitch is determined by the pitch of the memory cell region. Particularly in the sense amplifier or word line decoder of the peripheral circuit region, transistors may be arranged at small pitches. As the gate length decreases, the interval between gate electrodes and the distance between the gate and the contact may be decreased.

However, reduction in gate length poses the following problem: the short channel effect greatly varies the threshold, and a small threshold increases the standby current.

As a method of solving this problem, halo ion implantation is performed to suppress punch-through between the source and the drain at the gate edge and thereby suppress a decrease and variations in threshold voltage.

To perform halo ion implantation, an ionic species (e.g., B or BF₂ for an N-type MOSFET) of a type opposite to that which forms a diffusion layer may be implanted from a direction inclined to an axis perpendicular to a silicon substrate. For example, vertical ion implantation hardly increases the well concentration in a region where punch-through readily occurs in a gate edge region X. A rise of the well concentration in the diffusion layer region becomes prominent, and causes an increase in diffusion layer leakage current from the diffusion layer to the well region and an increase in diffusion layer capacitance. A large diffusion layer leakage current increases the standby current, and a large diffusion layer capacitance decreases the operating speed of the transistor. For this reason, halo ion implantation from an inclined direction is indispensable for suppression of the short channel effect.

However, the interval between the gate electrodes of adjacent cells narrows along with reduction in chip size. Halo ion implantation is inhibited by the gate electrodes of adjacent cells, and ions cannot be implanted into the gate edge region X.

Information on prior art references associated with the invention of the present application is as follows.

[Patent Reference 1] Jpn. Pat. No. 2663402

[Patent Reference 2] Jpn. Pat. Appln. KOKAI Publication No. 10-12847

[Patent Reference 3] U.S. Pat. No. 4,366,613

### BRIEF SUMMARY OF THE INVENTION

A semiconductor device according to a first aspect of the present invention comprises a semiconductor substrate having a first region, a second region, and a third region, a first gate insulating film which is formed on the semiconductor substrate in the first region, a first electrode layer which is formed on the first gate insulating film, a first silicide layer which is formed on the first electrode layer, a first cap layer which is formed on the first silicide layer, a second gate insulating film which is formed on the semiconductor substrate in the second region, a second electrode layer which is formed on the second gate insulating film, a second silicide layer which is formed on the second electrode layer, and a second cap layer which is formed on the second silicide layer and is thinner than the first cap layer.

A semiconductor device according to a second aspect of the present invention comprises a semiconductor substrate having a first region and a second region, a first gate insulating film which is formed on the semiconductor substrate in the first region, a first electrode layer which is formed on the first gate insulating film, a first silicide layer which is formed on the first electrode layer, a first stopper layer which is formed on the first silicide layer, a first cap layer which is formed on the first stopper layer and formed from a material different from a material of the first stopper layer, a second gate insulating film which is formed on the semiconductor substrate in the second region, a second electrode layer which is formed on the second gate insulating film, a second silicide layer which is formed on the second electrode layer, and a second stopper layer which is formed on the second silicide layer and is thinner than the first cap layer.

A semiconductor device manufacturing method according to a third aspect of the present invention comprises sequentially depositing a gate insulating film, an electrode layer, a silicide layer, a stopper layer, and a cap layer on a semiconductor substrate having a first region and a second region, patterning the gate insulating film, the electrode layer, the silicide layer, the stopper layer, and the cap layer to form in the first region a first gate structure of a first gate insulating film, a first electrode layer, a first silicide layer, a first stopper layer, and a first cap layer, and form in the second region a second gate structure of a second gate insulating film, a second electrode layer, a second silicide layer, a second stopper layer, and a second cap layer, removing the second cap layer by using the second stopper layer as a stopper, and forming a first diffusion layer by ion implantation in the semiconductor substrate in the first region and forming a second diffusion layer by halo ion implantation in the semiconductor substrate in the second region.

### BRIEF DESCRIPTION OF THE SEVERAL VIEWS OF THE DRAWING

FIG. 1 is a sectional view showing a semiconductor device according to the first embodiment of the present invention;

FIGS. 2 to 4 are sectional views respectively showing steps of manufacturing a semiconductor device according to the first embodiment of the present invention;

FIG. 5 is a sectional view showing a semiconductor device according to the second embodiment of the present invention;

FIG. 6 is a sectional view showing a semiconductor device according to the third embodiment of the present invention;

FIGS. 7 to 9 are sectional views respectively showing steps of manufacturing a semiconductor device according to the third embodiment of the present invention;

FIG. 10 is a sectional view showing an SAC process step for a semiconductor device in the memory cell array region according to the embodiments of the present invention; and

FIG. 11 is a sectional view showing a halo ion implantation step for a semiconductor device according to the prior art.

### DETAILED DESCRIPTION OF THE INVENTION

Preferred embodiments of the present invention will be described below with reference to the several views of the accompanying drawing. In the following description, the same reference numerals denote the same parts throughout the drawing.

### First Embodiment

The first embodiment makes a gate stack structure in the peripheral circuit region lower than that in the memory cell array region.

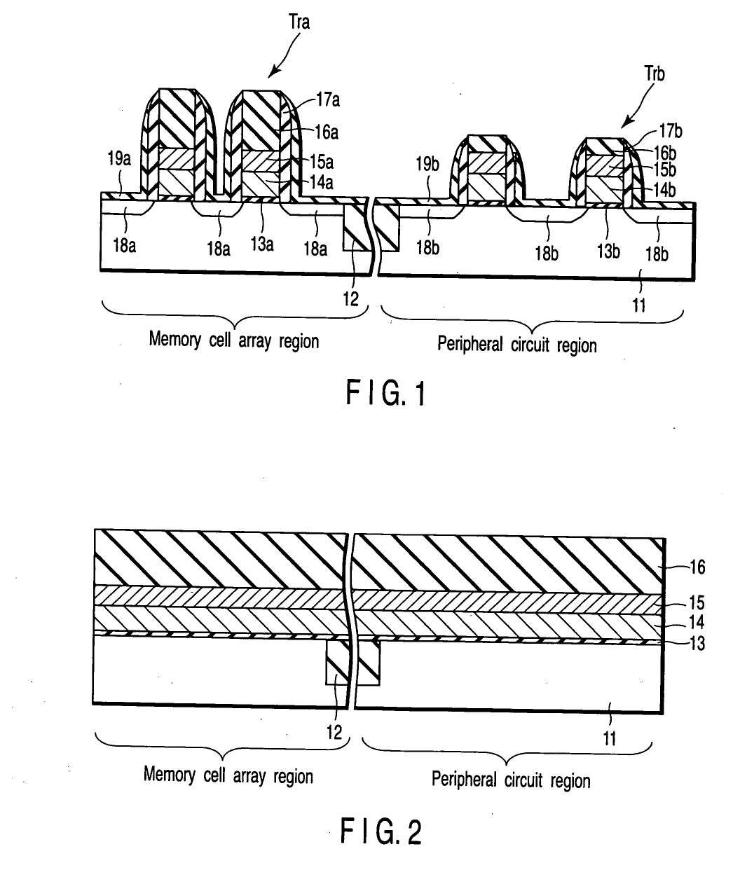

FIG. 1 is a sectional view of a semiconductor device according to the first embodiment of the present invention. The structure of the semiconductor device according to the first embodiment will be described.

As shown in FIG. 1, transistors Tra and Trb are respectively formed in the memory cell array region and peripheral circuit region. The transistors Tra and Trb have the following structures.

In the memory cell array region, a gate insulating film 13a is formed on a semiconductor substrate 11, and a gate electrode layer 14a is formed on the gate insulating film 13a. A silicide layer 15a is formed on the gate electrode layer 14a, and a cap layer 16a is formed on the silicide layer 15a. A side wall layer 17a is formed on the side surfaces of the gate insulating film 13a, gate electrode layer 14a, silicide layer 15a, and cap layer 16a. Diffusion layers 18a are formed in the surface of the semiconductor substrate 11. An insulating film 19a is formed on the semiconductor substrate 11 and side wall layer 17a.

Similarly in the peripheral circuit region, a gate insulating film 13b is formed on the semiconductor substrate 11, and a gate electrode layer 14b is formed on the gate insulating film 13b. A silicide layer 15b is formed on the gate electrode layer 14b, and a cap layer 16b is formed on the silicide layer 15b. A side wall layer 17b is formed on the side surfaces of the gate insulating film 13b, gate electrode layer 14b, silicide layer 15b, and cap layer 16b. Diffusion layers 18b are formed in the surface of the semiconductor substrate 11. An insulating film 19b is formed on the semiconductor substrate 11 and side wall layer 17b.

In the transistors Tra and Trb of the memory cell array region and peripheral circuit region, the cap layer 16b in the peripheral circuit region is thinner than the cap layer 16a in the memory cell array region. For example, the film thickness of the cap layer 16a is 2,200 Å, whereas that of the cap layer 16b is 500 Å which is smaller by 500 Å or more than the film thickness of the cap layer 16a. In other words, the film thickness of the cap layer 16b is, e.g., 25% or less of that of the cap layer 16a.

The film thickness of the cap layer 16b is desirably equal to or larger than that of the insulating film 19b. This setting can suppress over-etching of the cap layer 16b in etching the insulating film 19b and cap layer 16b when a contact to be connected to the gate electrode layer 14b and a contact to be connected to the diffusion layer 18b are simultaneously formed. Since the film thickness of the insulating film 19b is, e.g., about 80 Å, that of the cap layer 16b is desirably about 80 Å or more. In short, the film thickness of the cap layer 16b is desirably about 80 to 500 Å.

The cap layers 16a and 16b may be formed from the same material or different materials. For example, the cap layers 16a and 16b are formed from a silicon nitride film or silicon oxide film.

The cap layer 16b is desirably formed from the same material as that of the insulating film 19b. For example, the cap layer 16b is formed from a silicon nitride film.

The film thickness of the side wall layer 17b in the peripheral circuit region can be decreased to, e.g., ½ or less that of the side wall layer 17a in the memory cell array region. For example, the film thickness of the side wall layer 17a is 300 Å, whereas that of the side wall layer 17b is 100 Å. That is, the film thickness of the side wall layer 17b in the peripheral circuit region can also be decreased to about ⅓ that of the side wall layer 17a in the memory cell array region. When the side wall layers 17a and 17b are set to different film thicknesses, they can be formed from insulating films of different materials. For example, the side wall layer 17a is formed from a nitride film such as a silicon nitride film, and the side wall layer 17b is formed from an oxide film such as a TEOS (Tetra Ethyl Ortho Silicate) film.

The gate insulating film 13a, gate electrode layer 14a, and silicide layer 15a in the memory cell array region, and the gate insulating film 13b, gate electrode layer 14b, and silicide layer 15b in the peripheral circuit region, are respectively formed from the same materials at almost the same thicknesses. For example, the gate insulating films 13a and 13b are formed from an oxide film with a thickness of about 50 Å. The gate electrode layers 14a and 14b are formed from phosphorus-containing polysilicon with a thickness of about 700 Å. The silicide layers 15a and 15b are formed from tungsten silicide with a thickness of about 550 Å.

FIGS. 2 to 4 are sectional views respectively showing steps of manufacturing a semiconductor device according to the first embodiment of the present invention. The semiconductor device manufacturing method according to the first embodiment will be explained.

As shown in FIG. 2, an element isolation region 12 with an STI (Shallow Trench Isolation) structure is formed in a semiconductor substrate 11. A well region (not shown) is formed in the semiconductor substrate 11 by ion implantation. The semiconductor substrate 11 is oxidized in a dry atmosphere at, e.g., 900° C. to form a gate insulating film 13 to, e.g., 50 Å on the semiconductor substrate 11. A phosphorus-containing polysilicon film 14 is formed to, e.g., 700 Å on the gate insulating film 13. A tungsten silicide layer 15 is formed to, e.g., 550 Å on the polysilicon film 14. A cap layer 16 of a silicon nitride film is formed to, e.g., 2,200 Å on the tungsten silicide layer 15 by LPCVD (Low Pressure Chemical Vapor Deposition).

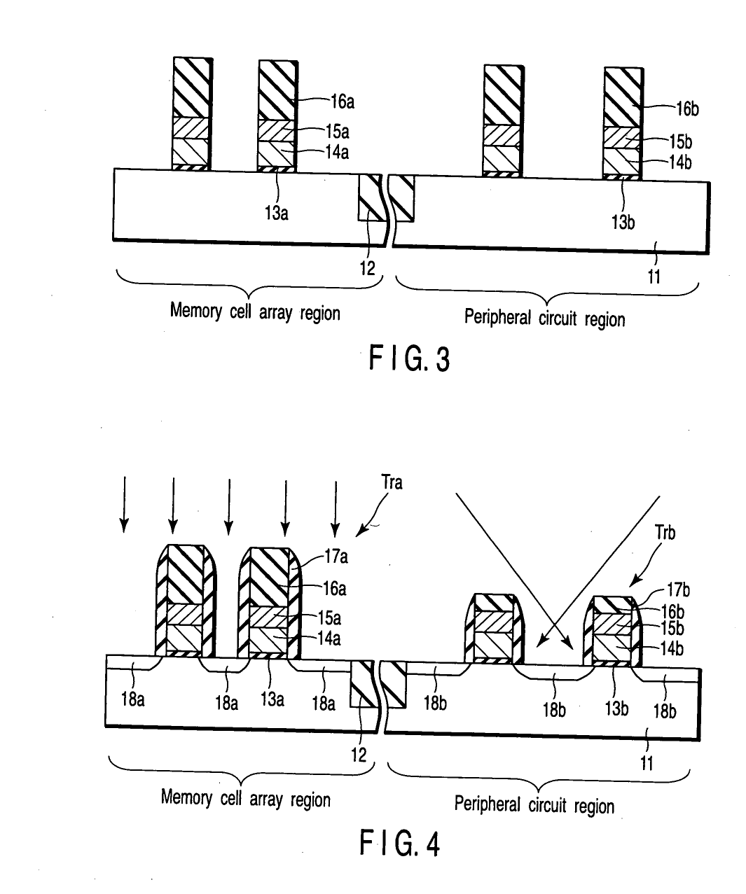

As shown in FIG. 3, gate patterns with gate stack structures are respectively formed in the memory cell array region and peripheral circuit region by lithography and dry etching. The gate stack structure in the memory cell array region is formed of the gate insulating film 13a, gate electrode layer 14a, silicide layer 15a, and cap layer 16a. The gate stack structure in the peripheral circuit region is formed of the gate insulating film 13b, gate electrode layer 14b, silicide layer 15b, and cap layer 16b.

As shown in FIG. 4, a mask (not shown) which exposes the gate stack structure in the peripheral circuit region is formed. The top of the cap layer 16b in the peripheral circuit region is removed using the mask. This makes the cap layer 16b in the peripheral circuit region thinner than the cap layer 16a in the memory cell array region. Side wall layers 17a and 17b are respectively formed on the side surfaces of the gate stack structures. The side wall layers 17a and 17b can be formed simultaneously or separately. After that, diffusion layers 18a are formed by ion implantation in the memory cell array region. Diffusion layers 18b are formed by halo ion implantation in the peripheral circuit region. As a result, transistors Tra and Trb are respectively formed.

As shown in FIG. 1, insulating films 19a and 19b are formed on the semiconductor substrate 11 and the side wall layers 17a and 17b. A general interlayer dielectric film burying step and interconnection formation step follow, and a description thereof will be omitted.

As described above, according to the first embodiment, the cap layer 16b in the peripheral circuit region is thinner than the cap layer 16a in the memory cell array region. In the peripheral circuit region, the cap layer 16b of the adjacent cell does not function as an obstacle even in a region where the interval between the gates of adjacent cells becomes smaller along with reduction in chip size. Halo ion implantation can be stably done in the gate edge region. This can suppress the short channel effect while reducing the chip area.

### Second Embodiment

The second embodiment is a modification to the first embodiment. The peripheral circuit region includes two types of gate stack structure: a low-profile stack structure and normal stack structure.

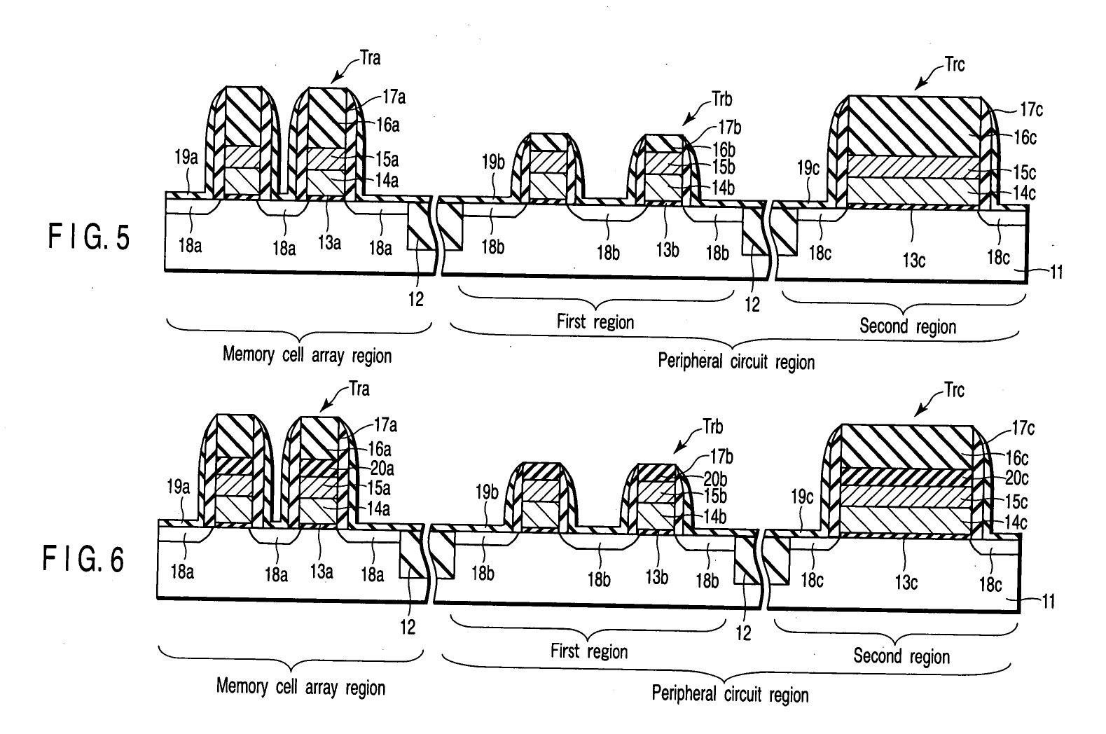

FIG. 5 is a sectional view of a semiconductor device according to the second embodiment of the present invention. The structure of the semiconductor device according to the second embodiment will be explained.

As shown in FIG. 5, the second embodiment is different from the first embodiment in that two types of gate stack structure exist in the peripheral circuit region, a transistor Trb with a low-profile stack structure is formed in the first region of the peripheral circuit region, and a transistor Trc with the same normal stack structure as that in the memory cell array region is formed in the second region of the peripheral circuit region. The memory cell array region and the first region of the peripheral circuit region have the same gate stack structures as those in the first embodiment, and a description thereof will be omitted.

In the second region of the peripheral circuit region, a gate insulating film 13c is formed on a semiconductor substrate 11, and a gate electrode layer 14c is formed on the gate insulating film 13c. A silicide layer 15c is formed on the gate electrode layer 14c, and a cap layer 16c is formed on the silicide layer 15c. A side wall layer 17c is formed on the side surfaces of the gate insulating film 13c, gate electrode layer 14c, silicide layer 15c, and cap layer 16c. Diffusion layers 18c are formed in the surface of the semiconductor substrate 11. An insulating film 19c is formed on the semiconductor substrate 11 and side wall layer 17c.

The film thickness of the cap layer 16c in the second region of the peripheral circuit region is, e.g., 2,200 Å which is almost the same as that of a cap layer 16a in the memory cell array region. The cap layer 16c is formed from, e.g., a silicon nitride film. The cap layer 16c may be formed from the same material as or a different material from that of the cap layer 16a, but is desirably formed from the same material as that of the cap layer 16a.

The film thickness of the side wall layer 17c in the second region of the peripheral circuit region is, e.g., 300 Å which is almost the same as that of a side wall layer 17a in the memory cell array region. The side wall layer 17c is formed from, e.g., a silicon nitride film. The side wall layer 17c may be formed from the same material as or a different material from that of a side wall layer 17b, but is desirably formed from the same material as that of the side wall layer 17a.

The gate insulating film 13c, gate electrode layer 14c, and silicide layer 15c in the second region of the peripheral circuit region are respectively formed from the same materials at almost the same thicknesses as those of gate insulating films 13a and 13b, gate electrode layers 14a and 14b, and silicide layers 15a and 15b in the memory cell array region and the first region of the peripheral circuit region.

Peripheral circuits present in the peripheral circuit region are, e.g., a sense amplifier, row decoder (word line decoder or the like), column decoder (bit-line decoder or the like), row address buffer, column address buffer, data input/output buffer, row control circuit, column control circuit, and bias circuit (voltage generation circuit or the like). Particularly in the sense amplifier and word line decoder out of these peripheral circuits, transistors may be arranged at small pitches. For this purpose, halo ion implantation may be stably performed by forming the gate stack structure into a low profile. The sense amplifier and word line decoder are, therefore, desirably formed in the first region of the peripheral circuit region. In addition to the sense amplifier or word line decoder, even a peripheral circuit which requires arrangement of transistors at small pitches is also desirably formed in the first region of the peripheral circuit region.

As described above, the second embodiment can obtain the same effects as those of the first embodiment.

The cap layer 16b in a partial region (first region) of the peripheral circuit region is made thin. The cap layer 16c in the peripheral circuit region except for this region is set to the same thickness as that of the cap layer 16a in the memory cell array region. This can suppress any difference in pattern density, and can suppress dishing in a planarization step for an interlayer dielectric film deposited on the gate stack structure. Hence, the second embodiment can avoid any problems caused by dishing, such as insufficient etching in processing caused by burying an interconnection in the dishing region in an interconnection formation step, and generation of a metal residue in a CMP (Chemical Mechanical Polish) step in forming a buried interconnection.

The region where the cap layer is made thin in the gate stack structure can be restricted to a predetermined region (first region) of the peripheral circuit region. Thus, the cap layer can be made thin only in a portion at which the short channel effect is to be suppressed in the peripheral circuit.

### Third Embodiment

The third embodiment is a modification to the second embodiment. A stopper layer is formed in the gate stack structure.

FIG. 6 is a sectional view of a semiconductor device manufacturing step according to the third embodiment of the present invention. The structure of the semiconductor device according to the third embodiment will be explained.

As shown in FIG. 6, the third embodiment is different from the second embodiment in that stopper layers 20a, 20b, and 20c are formed on silicide layers 15a, 15b, and 15c, and cap layers 16a and 16c exist in the memory cell array region and the second region of the peripheral circuit region but no cap layer exists in the first region of the peripheral circuit region.

The stopper layers 20a, 20b, and 20c have almost the same film thickness of, e.g., 100 Å in all regions, but can also have different film thickness. The film thicknesses of the stopper layers 20a, 20b, and 20c are smaller than those of the cap layers 16a and 16c by, e.g., 500 Å or more, and are desirably set to, e.g., 25% or less of those of the cap layers 16a and 16c.

The stopper layers 20a, 20b, and 20c are formed from an oxide film such as a TEOS or silicon oxide film. The stopper layers 20a, 20b, and 20c are desirably formed from a material different from that of the cap layers 16a and 16c, and from the same material as that of an insulating film 19b. When the stopper layers 20a, 20b, and 20c are formed from the same material as that of the insulating film 19b, the film thicknesses of the stopper layers 20a, 20b, and 20c are desirably equal to or larger than that (e.g., 80 Å) of the insulating film 19b.

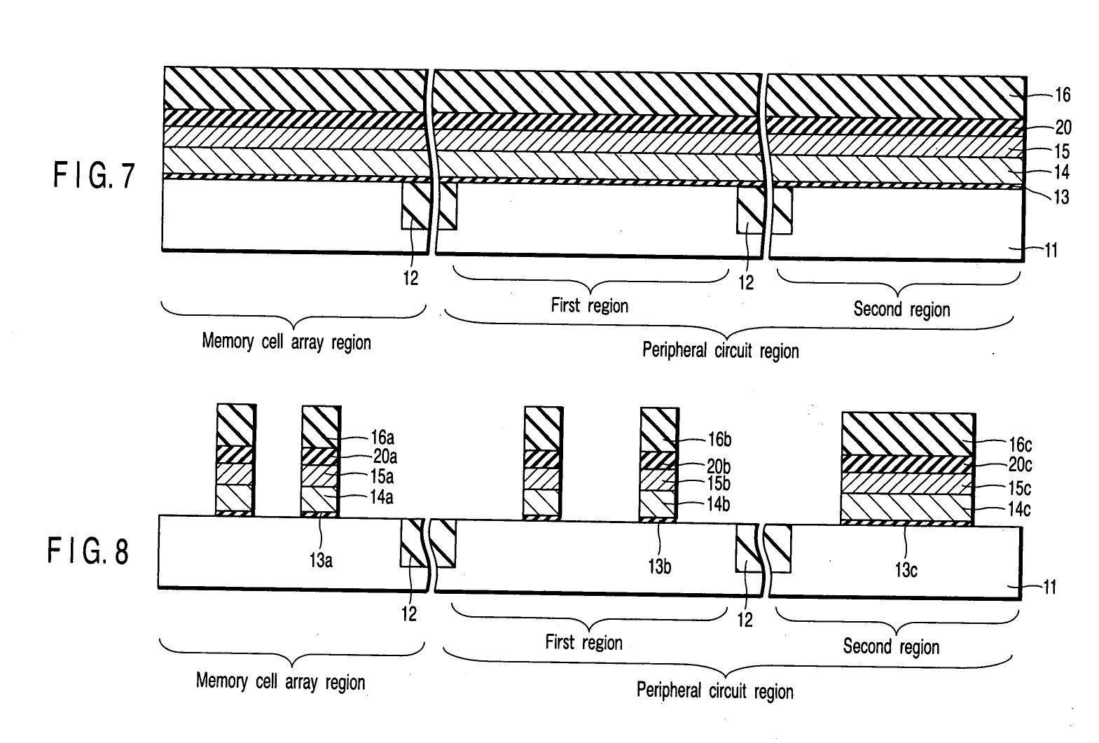

FIGS. 7 to 9 are sectional views respectively showing steps of manufacturing a semiconductor device according to the third embodiment of the present invention. The semiconductor device manufacturing method according to the third embodiment will be explained.

As shown in FIG. 7, an element isolation region 12 with the STI structure is formed in a semiconductor substrate 11. A well region (not shown) is formed in the semiconductor substrate 11 by ion implantation. The semiconductor substrate 11 is oxidized in a dry atmosphere at, e.g., 900° C. to form a gate insulating film 13 of, e.g., 50 Å on the semiconductor substrate 11. A phosphorus-containing polysilicon film 14 is formed to have a thickness of, e.g., 1,000 Å on the gate insulating film 13. A tungsten silicide layer 15 is formed to have a thickness of, e.g., 1,000 Å on the polysilicon film 14. A TEOS stopper layer 20 is formed to have a thickness of, e.g., 100 Å on the tungsten silicide layer 15. A cap layer 16 of a silicon nitride film is formed to have a thickness of, e.g., 2,000 Å on the stopper layer 20 by LPCVD.

As shown in FIG. 8, gate patterns with gate stack structures are respectively formed in the memory cell array region and peripheral circuit region by lithography and dry etching. The gate stack structure in the memory cell array region is formed of a gate insulating film 13a, gate electrode layer 14a, silicide layer 15a, stopper layer 20a, and cap layer 16a. The gate stack structure in the first region of the peripheral circuit region is formed of a gate insulating film 13b, gate electrode layer 14b, silicide layer 15b, stopper layer 20b, and cap layer 16b. The gate stack structure in the second region of the peripheral circuit region is formed of a gate insulating film 13c, gate electrode layer 14c, silicide layer 15c, stopper layer 20c, and cap layer 16c.

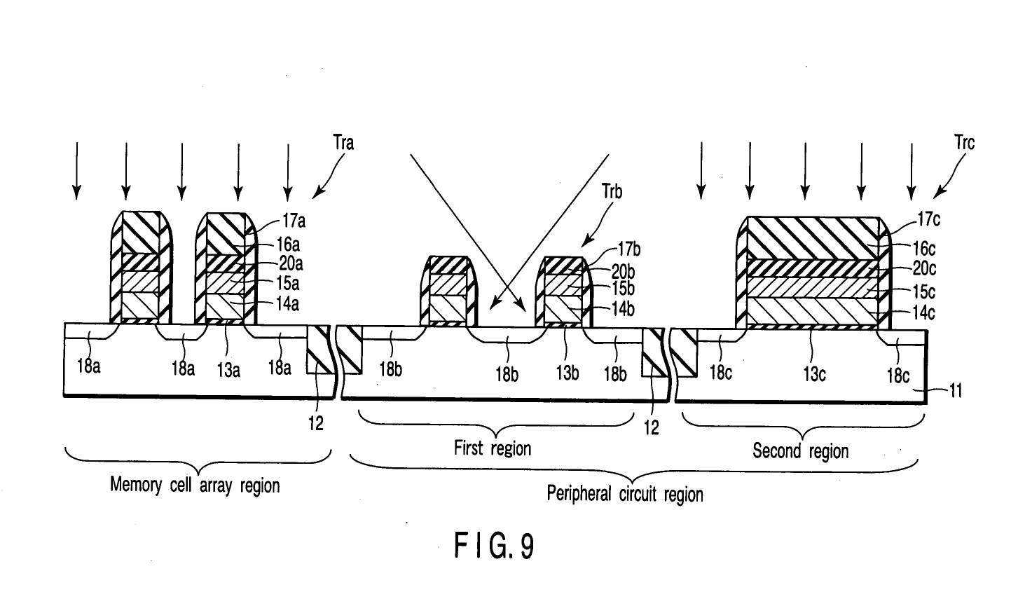

As shown in FIG. 9, a resist (not shown) is applied after post-oxidization. Only the resist in the first region of the peripheral circuit region is selectively peeled by lithography. The cap layer 16b in the first region of the peripheral circuit region is peeled with hot phosphoric acid using the stopper layer 20b as a stopper. Thereafter, the resist is peeled. Side wall layers 17a, 17b, and 17c are respectively formed on the side surfaces of the gate stack structures. The side wall layers 17a, 17b, and 17c can be formed simultaneously or separately. Diffusion layers 18a and 18c are formed by ion implantation in the memory cell array region and the second region of the peripheral circuit region. Diffusion layers 18b are formed by halo ion implantation in the first region of the peripheral circuit. Consequently, transistors Tra, Trb, and Trc are respectively formed.

As shown in FIG. 6, insulating films 19a, 19b, and 19c are formed on the semiconductor substrate 11 and the side wall layers 17a, 17b, and 17c. A general interlayer dielectric film burying step and interconnection formation step follow, and a description thereof will be omitted.

As described above, the third embodiment can achieve the same effects as those of the second embodiment.

Further, the third embodiment forms the stopper layers 20a, 20b, and 20c below the cap layers 16a, 16b, and 16c. The stopper layer 20b functions as a stopper in peeling the cap layer 16b from the first region of the peripheral circuit region. Thus, the cap layer 16b can be stably peeled.

The third embodiment is applied to the second embodiment, and can also be applied to the first embodiment.

As has been described above, the above embodiments make the gate stack structure in the peripheral circuit region into a low profile. To stably perform halo ion implantation, the gate stack structure in the memory cell array region may also be formed into a low profile as well as that in the peripheral circuit region. However, it is generally difficult to form the gate stack structure in the memory cell array region into a low profile for the following reason.

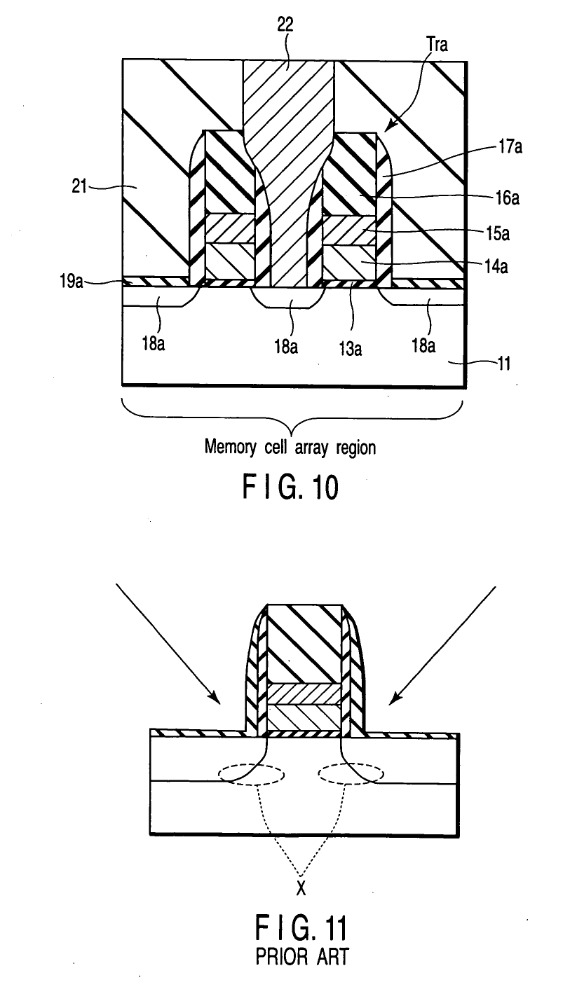

For example, a DRAM requires an SAC (Self Align Contact) process in order to form a memory cell structure. In the SAC process, as shown in FIG. 10, a silicon nitride film (cap layer 16a and side wall layer 17a) which is so formed as to surround the gate is selectively left in processing an interlayer dielectric film 21 in order to form a bit line contact 22. The contact 22 is formed in a self-aligned manner between the gate electrodes of a cell array. The gate of the DRAM generally has a three-layer structure of the gate electrode layer 14a, silicide layer 15a, and cap layer 16a. The cap layer 16a may be set to a film thickness at which the cap layer 16a sufficiently remains so as not to etch the silicide layer 15a and gate electrode layer 14a after the interlayer dielectric film 21 is etched in the SAC process. For this reason, the cap layer 16a may be as thick as about 1,000 to 5,000 Å. It is very difficult to make the cap layer 16a thin in the memory cell array region.

However, the gate stack structure can also be formed into a low profile even in the memory cell array region as far as the above-described problem of the SAC process can be avoided.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a semiconductor substrate having a first region and a second region;
a first gate insulating film which is formed on the semiconductor substrate in the first region;
a first electrode layer which is formed on the first gate insulating film;
a first silicide layer which is formed on the first electrode layer;
a first cap layer which is formed on the first silicide layer;
a second gate insulating film which is formed on the semiconductor substrate in the second region;
a second electrode layer which is formed on the second gate insulating film;
a second silicide layer which is formed on the second electrode layer; and
a second cap layer which is formed on the second silicide layer and is thinner than the first cap layer.

2. The device according to claim 1, wherein a film thickness of the second cap layer is not more than 25% of a film thickness of the first cap layer.

3. The device according to claim 1, wherein a film thickness of the second cap layer is smaller by not less than 500 Å than a film thickness of the first cap layer.

4. The device according to claim 1, wherein a film thickness of the second cap layer is from 80 to 500 Å.

5. The device according to claim 1, which further comprises a first insulating film formed on the semiconductor substrate, and in which a film thickness of the second cap layer is not less than a film thickness of the first insulating film.

6. The device according to claim 5, wherein the second cap layer is formed from a same material as a material of the first insulating film.

7. The device according to claim 1, further comprising:
a first side wall layer which is formed on side surfaces of the first gate insulating film, the first gate electrode layer, the first silicide layer, and the first cap layer; and
a second side wall layer which is formed on side surfaces of the second gate insulating film, the second gate electrode layer, the second silicide layer, and the second cap layer and is thinner than the first side wall layer.

8. The device according to claim 7, wherein a film thickness of the second side wall layer is not more than ½ of a film thickness of the first side wall layer.

9. The device according to claim 7, wherein the second side wall layer is formed from a material different from a material of the first side wall layer.

10. The device according to claim 7, wherein the first side wall layer is formed from a nitride film, and the second side wall layer is formed from an oxide film.

11. The device according to claim 1, wherein the first region includes a memory cell array regions and the second region includes a peripheral circuit region.

12. The device according to claim 1, further comprising:
a third gate insulating film which is formed on the semiconductor substrate in a third region;
a third electrode layer which is formed on the third gate insulating film;
a third silicide layer which is formed on the third electrode layer; and
a third cap layer which is formed on the third silicide layer and is substantially as thick as the first cap layer.

13. The device according to claim 12, wherein the first region includes a memory cell array region, and the second region and the third region include a peripheral circuit region.

14. The device according to claim 13, wherein a peripheral circuit present in the second region includes a sense amplifier and a word line decoder.

15. A semiconductor device comprising:
a semiconductor substrate having a first region and a second region;
a first gate insulating film which is formed on the semiconductor substrate in the first region;
a first electrode layer which is formed on the first gate insulating film;
a first silicide layer which is formed on the first electrode layer;
a first stopper layer which is formed on the first silicide layer;
a first cap layer which is formed on the first stopper layer and formed from a material different from a material of the first stopper layer;
a second gate insulating film which is formed on the semiconductor substrate in the second region;
a second electrode layer which is formed on the second gate insulating film;
a second silicide layer which is formed on the second electrode layer; and
a second stopper layer which is formed on the second silicide layer and is thinner than the first cap layer.

16. The device according to claim 15, wherein a film thickness of the second stopper layer is not more than 25% of a film thickness of the first cap layer.

17. The device according to claim 15, wherein a film thickness of the second stopper layer is substantially equal to a film thickness of the first stopper layer.

18. A semiconductor device manufacturing method comprising:
sequentially depositing a gate insulating film, an electrode layer, a silicide layer, a stopper layer, and a cap layer on a semiconductor substrate having a first region and a second region;
patterning the gate insulating film, the electrode layer, the silicide layer, the stopper layer, and the cap layer to form in the first region a first gate structure of a first gate insulating film, a first electrode layer, a first silicide layer, a first stopper layer, and a first cap layer, and form in the second region a second gate structure of a second gate insulating film, a second electrode layer, a second silicide layer, a second stopper layer, and a second cap layer;
removing the second cap layer by using the second stopper layer as a stopper; and
forming a first diffusion layer by ion implantation in the semiconductor substrate in the first region and forming a second diffusion layer by halo ion implantation in the semiconductor substrate in the second region.

19. The method according to claim 18, wherein a film thickness of the stopper layer is smaller than a film thickness of the cap layer.

20. The method according to claim 18, wherein the stopper layer is formed from a material different from a material of the cap layer.
